(19) United States
(12) Patent Application Publication
(10) Pub. No.: US 2026/0324465 A1
(43) Pub. Date: Oct. 15, 2026

(54) SUBSTRATE STRUCTURE OF ELECTRONIC DEVICE AND MANUFACTURING METHOD OF ELECTRONIC DEVICE

(71) Applicant: InnoLux Corporation, Miao-Li county (TW)

(72) Inventors: Chia-Ping TSENG, Miao-Li county (TW); Po-Yun HSU, Miao-Li county (TW); Chun-Chin FAN, Miao-Li county (TW)

(73) Assignee: InnoLux Corporation, Miao-Li county (TW)

(21) Appl. No.: 19/568,726

(22) Filed: Mar. 16, 2026

Related U.S. Application Data
(60) Provisional application No. 63/781,387, filed on Apr. 1, 2025.

(30) Foreign Application Priority Data
Jan. 13, 2026 (CN) 202610042033.5

(51) Int. Cl. H10W 70/63; H10W 70/05; H10W 70/652; H10W 70/692

(52) U.S. Cl. CPC H10W 70/635; H10W 70/095; H10W 70/652; H10W 70/692

(57) ABSTRACT

Provided are a substrate structure of an electronic device and a method for manufacturing the same. The substrate structure of the electronic device comprises a substrate, a plurality of through holes penetrate the substrate, and a conductive member disposed in at least one of the plurality of through holes. A pitch between two adjacent through holes of the plurality of through holes is less than or equal to 200 μm. In a cross-sectional view of the substrate structure, the conductive member has a bridge, a first portion, a second portion, and a third portion sequentially disposed along a normal direction of the substrate. The bridge is adjacent to a sidewall of the at least one of the plurality of through holes. The first portion is adjacent to a sidewall of the bridge, and the first portion has an average grain size less than or equal to 5 μm.

### CROSS REFERENCE TO RELATED APPLICATION

This application claims the benefit of U.S. Provisional Application No. 63/781,387, filed on Apr.1^{st}, 2025. The content of the application is incorporated herein by reference.

### BACKGROUND OF THE DISCLOSURE

### 1. Field of the Disclosure

The present disclosure relates to an electronic device, and more particularly, to a design of an electronic device having a substrate structure and a manufacturing method thereof.

### 2. DESCRIPTION OF THE PRIOR ART

In the process of forming an electronic device, an electroplating process is utilized to form conductive members in through holes of a substrate to form a substrate structure. However, the material of conductive members formed by existing electroplating processes may have relatively large grain sizes and/or different crystallinities. During subsequent processes for forming the electronic device, the substrate structure is prone to cracking after undergoing thermal processes. This can cause abnormal signal transmission in the formed electronic device, thereby reducing the reliability of the electronic device.

### SUMMARY OF THE DISCLOSURE

The present disclosure is directed to a substrate structure of an electronic device. The electronic device comprising the substrate structure can have relatively high reliability.

According to some embodiments of the present disclosure, a substrate structure of an electronic device comprises a substrate, a plurality of through holes, and a conductive member. The plurality of through holes penetrate the substrate, wherein a pitch between two adjacent through holes of the plurality of through holes is less than or equal to 200 μm. The conductive member is disposed in at least one of the plurality of through holes. In a cross-sectional view of the substrate structure, the conductive member has a bridge, a first portion, a second portion, and a third portion sequentially disposed along a normal direction of the substrate. The bridge is adjacent to a sidewall of the at least one of the plurality of through holes. The first portion is adjacent to a sidewall of the bridge, and the first portion has an average grain size less than or equal to 5 μm.

The present disclosure is directed to a manufacturing method of an electronic device. The electronic device manufactured by the method can have relatively high reliability.

According to some embodiments of the present disclosure, a manufacturing method of an electronic device comprises the following steps. A substrate structure is provided, which comprises the following steps. A substrate having a plurality of through holes is provided. An electroplating process is performed to form a conductive member in at least one of the plurality of through holes, comprising: performing a first electroplating process to form a bridge in at least one of the plurality of through holes, with the bridge being adjacent to a sidewall of the at least one of the plurality of through holes, followed by performing a second electroplating process to form other portions of the conductive member connected to the bridge in the at least one of the plurality of through holes. In a cross-sectional view of the substrate structure, the other portions of the conductive member have a first portion, a second portion, and a third portion sequentially disposed along a normal direction of the substrate. The first portion is adjacent to a sidewall of the bridge, and the first portion has an average grain size less than or equal to 5 μm. A pitch between two adjacent through holes of the plurality of through holes is less than or equal to 200 μm. At least one process is performed to form the electronic device. A current density and an electroplating time used in the first electroplating process are greater than a current density and an electroplating time used in the second electroplating process.

### BRIEF DESCRIPTION OF THE DRAWINGS

The drawings are included to provide a further understanding of the disclosure, and the drawings are incorporated in and constitute a part of this specification. The drawings illustrate embodiments of the disclosure and, together with the description, serve to explain the principles of the disclosure.

FIG. 1 is a schematic flowchart of a manufacturing method of an electronic device according to an embodiment of the present disclosure.

FIG. 2 is a schematic cross sectional view of a substrate structure in an electronic device according to an embodiment of the present disclosure.

FIG. 3A is a scanning electron microscope photograph of an embodiment of the region R1 in FIG. 2.

FIG. 3B is a scanning electron microscope photograph of an embodiment of the region R2 in FIG. 2.

FIG. 4 is a schematic top view of a portion of a substrate structure in an electronic device according to an embodiment of the present disclosure.

FIG. 5 is a schematic cross sectional view of an electronic device according to an embodiment of the present disclosure.

### DETAILED DESCRIPTION

Reference will now be made in detail to the exemplary embodiments of the present disclosure, examples of which are illustrated in the accompanying drawings. Wherever possible, the same reference numbers are used in the drawings and the description to refer to the same or like parts.

The present disclosure can be understood by reference to the following detailed description in conjunction with the accompanying drawings. It should be noted that, for ease of understanding for the reader and for the conciseness of the drawings, many of the drawings in the present disclosure depict only a part of the electronic device, and specific elements in the drawings are not drawn to actual scale. In addition, the quantity and size of each element in the figures are for illustrative purposes only and are not intended to limit the scope of the present disclosure.

Throughout this specification and the appended claims, certain terms are used to refer to specific components. Those skilled in the art should understand that electronic device manufacturers may refer to the same component by different names. This document does not intend to distinguish between components that have the same function but different names. In the following description and in the claims, words such as "comprising," "containing," "having," and the like are open-ended terms and should therefore be interpreted as "comprising, but not limited to...". Therefore, when the terms "comprising," "containing," and/or "having" are used in the description of the present disclosure, they specify the presence of corresponding features, regions, steps, operations, and/or components, but do not preclude the presence of one or more other corresponding features, regions, steps, operations, and/or components.

Directional terms mentioned herein, such as "up," "down," "front," "back," "left," "right," etc., are only for reference to the orientation of the accompanying drawings. Therefore, the directional terms used are for illustration and not for limiting the present disclosure. In the drawings, each figure shows the general features of the method, structure, and/or materials used in a particular embodiment. However, these drawings should not be construed as defining or limiting the scope or nature covered by these embodiments.

When a corresponding component (e.g., a film layer or a region) is referred to as being "on another component," it can be directly on the other component, or other components may be present between them. On the other hand, when a component is referred to as being "directly on another component," there are no components between them. In addition, when a component is referred to as being "on another component," they have a top-down relationship in a top view direction, and this component can be above or below the other component, and this top-down relationship depends on the orientation of the device.

The terms "equal to" or "same," "substantially" or "approximately" are generally interpreted as being within 20% of a given value or range, or as being within 10%, 5%, or 0.5% of a given value or range.

Ordinal numbers such as "first," "second," etc., used in the specification and claims are used to modify elements and do not in themselves imply or represent that the element(s) have any preceding ordinal number, nor do they represent the order of one element with respect to another, or the order in a manufacturing method. The use of these ordinal numbers is only to clearly distinguish an element with a certain name from another element with the same name. The claims and the specification may not use the same terms. Accordingly, a first component in the specification may be a second component in the claims.

It should be understood that the features in several different embodiments may be substituted to complete other embodiments without departing from the spirit of the present disclosure. As long as the features of various embodiments do not contradict the spirit of the disclosure or conflict with each other, they can be arbitrarily mixed and matched.

The electrical connections or couplings described in the present disclosure may refer to either direct connections or indirect connections. In the case of a direct connection, the terminals of two circuit elements are directly connected or connected to each other by a conductive line segment. In the case of an indirect connection, other suitable elements are present between the terminals of the two circuit elements.

In the present disclosure, the definition of thickness, length, width, area, and roughness can be determined by observation with an optical microscope, a scanning electron microscope, or a transmission electron microscope. On an uneven surface, the distance difference between the peaks and valleys of the surface undulations can be defined as the roughness of the uneven surface. The condition of the surface undulations is observed under an appropriate magnification of a microscope, and the roughness range is determined by comparing the undulation condition of a sample of a unit length (e.g., 10 micrometers). Here, "appropriate magnification" means that the roughness (Rz) or average roughness (Ra) of at least one surface can be seen with at least 10 undulating peaks in the field of view at this magnification.

The process of the electronic device of the present disclosure can be provided, for example, through a wafer-level package (WLP) process or a panel-level package (PLP) process, which can be a chip first or chip last / RDL first process.

The electronic device of the present disclosure can be applied to a power module, a semiconductor package device, a display device, a light-emitting device, a backlight device, an antenna device, a sensing device, or a tiling device, but is not limited thereto. The electronic device may have peripheral systems such as a driving system, a control system, a light source system, etc., to support a display device, an antenna device, a wearable device, an in-vehicle device, or a tiling device. The electronic device may comprise a package device such as a High Bandwidth Memory (HBM) package, a Chip on Wafer on Substrate (CoWoS) package structure, a System on a Chip (SoC), a System in a Package (SiP), an antenna in package (AiP), a Co-packaged Optics (CPO), or various combinations of the above devices, but is not limited thereto.

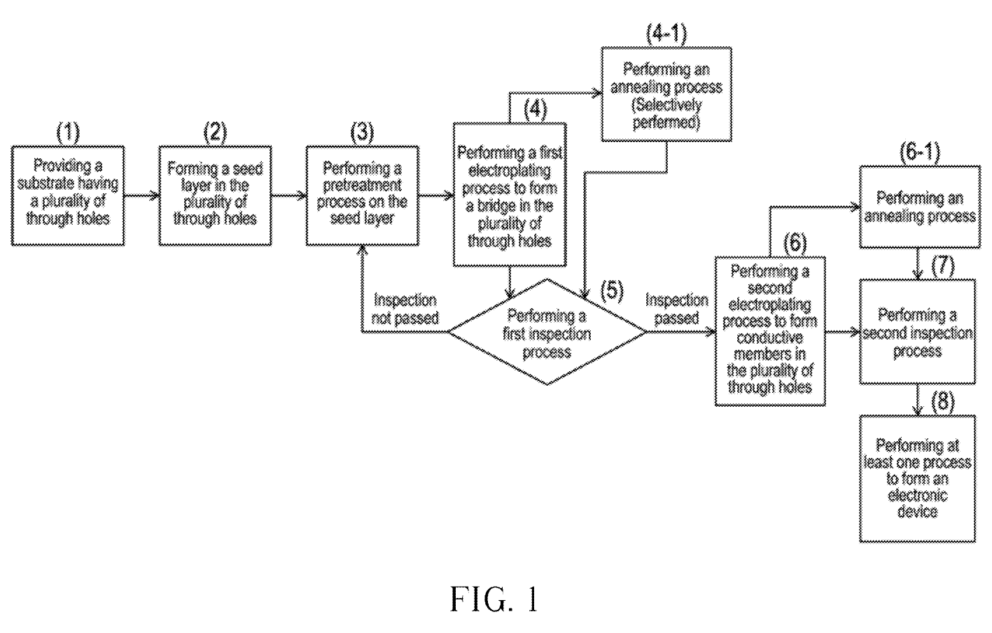

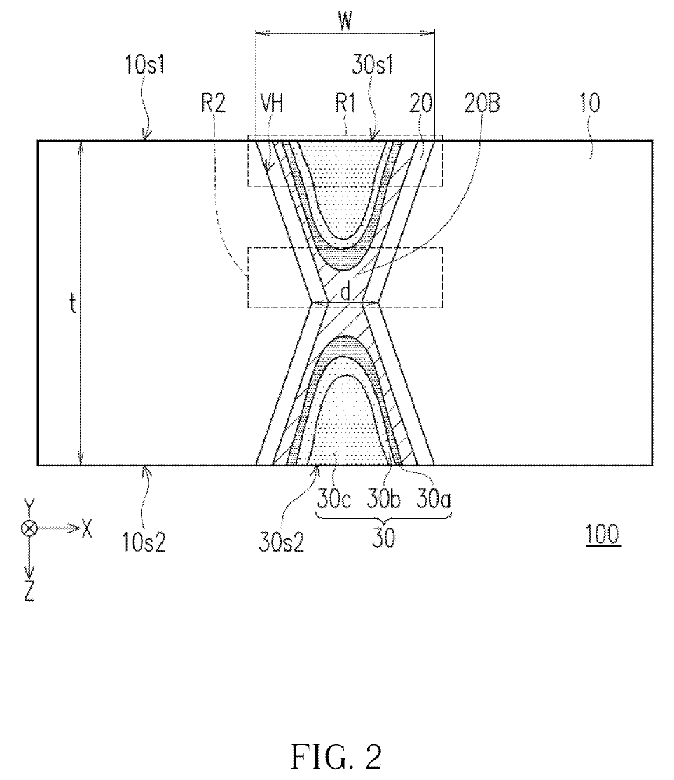

Please refer to FIGS. 1 and 2 simultaneously. In this embodiment, the electronic device 10c and the substrate structure of the electronic device 10c can be formed by performing the following steps, but the present disclosure is not limited thereto.

Step (1) is performed: forming a plurality of through holes VH penetrating the substrate 10.

The material of the substrate 10 may, for example, comprise a suitable ceramic material. For example, the material of the substrate 10 comprises a transparent material, glass, alkali-free glass, or quartz glass. In this embodiment, the substrate 10 is a glass substrate and has a surface 10s1 and a surface 10s2 opposite to each other in a direction Z (a normal direction of the substrate 10). A plurality of through holes VH penetrating the substrate 10 can be formed by performing a corresponding etching process and/or laser process on the substrate 10.

Step (2) is performed: forming a seed layer 20 in the plurality of through holes VH of the substrate 10.

The seed layer 20 can be formed by performing an electroless plating process, an electroplating process, an atomic layer deposition (ALD) process, a physical vapor deposition (PVD) process, a chemical vapor deposition (CVD) process, or a combination thereof. In this embodiment, the seed layer 20 may comprise a stacked multilayer structure. It is worth noting that the seed layer 20 can also be formed on the surface 10s1 and the surface 10s2 of the substrate 10.

Step (3) is performed: performing a pretreatment process on the seed layer 20.

In some embodiments, the pretreatment process performed on the seed layer 20 may comprise a cleaning process and/or a micro-etching process and/or a heat treatment. For example, a first cleaning process can be performed to remove seams and/or holes that appear where adjacent seed layers 20 in the through holes VH are connected. Afterwards, a micro-etching process can be performed on the seed layer 20 to give the seed layer 20 a rough surface, which can improve the bonding force with subsequently formed film layers. Next, a second cleaning process is performed to remove impurities formed in the aforementioned micro-etching process. After the pretreatment process is performed on the seed layer 20, step (2) can be selectively performed again to form another seed layer to improve the continuity of the seed layer.

Step (4) is performed: performing a first electroplating process to form a bridge 20B of the conductive member 30.

In this embodiment, the first electroplating process is a pulse periodic reverse (PPR) electroplating process. Specifically, the bridge 20B can be formed between adjacent seed layers 20 located in the through holes VH by independently adjusting the current-on time, the current-off time (electroplating time), and/or the current density. After the first electroplating process is performed, step (4-1), i.e., an annealing process, can be selectively performed.

Step (5) is performed: performing a first inspection process.

In this embodiment, the first inspection process comprises: (a) checking whether the bridge 20B is formed; and (b) checking the formation position of the bridge 20B. In step (a), if it is observed that the bridge 20B is not formed, the process returns to step (3). If it is observed that the bridge 20B has been formed, step (b) is performed to check whether the bridge 20B is located in a region extending from the surface 10s1 of the substrate 10 in the direction Z by 0.25 times the thickness t of the substrate 10 to 0.75 times the thickness t of the substrate 10. If it is observed that the bridge 20B is not formed in the aforementioned region, the process returns to step (3) and another pretreatment process is performed on the seed layer 20, for example, remove an oxidation layer of the seed layer 20 by any suitable process.

In some embodiments, the condition of the bridge 20B can be confirmed by an optical inspection system or a scanning electron microscope, but the present disclosure is not limited to. A cleaning process can be performed before the first inspection process.

Step (6) is performed: performing a second electroplating process to form other portions of the conductive member 30 connected to the bridge 20B to complete the conductive member 30.

The second electroplating process is, for example, a multi-stage direct current electroplating process. Specifically, the conductive member 30 comprising a first portion 30a, a second portion 30b, and a third portion 30c can be formed by performing a three-stage direct current electroplating process, wherein the first portion 30a, the second portion 30b, and the third portion 30c are sequentially disposed. Here, "sequentially disposed" means that the first portion 30a, the second portion 30b, and the third portion 30c are sequentially disposed along a direction (direction X or direction Y) perpendicular to the normal direction (direction Z) of the substrate, and the first portion 30a is adjacent to a sidewall of the bridge 20B. In this embodiment, the first portion 30a and the second portion 30b are conformally formed in the through hole VH, and the third portion 30c is filled into the through hole VH. In other words, the bridge 20B is used as a foundation to fill the through hole VH to complete the fabrication of the conductive member 30. The current densities and electroplating times used in the first electroplating process and the second electroplating process are different from each other. In this embodiment, the current density and the electroplating time of the first electroplating process are each greater than the current density and the electroplating time of the second electroplating process. In some embodiments, an average particle size of the third portion 30c is greater than or equal to an average particle size of the bridge 20B. The technical solution regarding particle size is detailed in the following embodiments.

In this embodiment, the current density in the three stages of the direct current electroplating process can sequentially increase, and the electroplating time in the three stages of the direct current electroplating process can sequentially decrease. Specifically, the current density in the direct current electroplating process for forming the first portion 30a is less than the current density in the direct current electroplating process for forming the second portion 30b, and the current density in the direct current electroplating process for forming the second portion 30b is less than the current density in the direct current electroplating process for forming the third portion 30c. In addition, the electroplating time in the direct current electroplating process for forming the first portion 30a is greater than the electroplating time in the direct current electroplating process for forming the second portion 30b, and the electroplating time in the direct current electroplating process for forming the second portion 30b is greater than the electroplating time in the direct current electroplating process for forming the third portion 30c.

By changing the current density and electroplating time in the three stages of the direct current electroplating process, the crystallization conditions in the first portion 30a, the second portion 30b, and the third portion 30c can be individually adjusted. This can reduce the stress generated due to different coefficients of thermal expansion between the layers during subsequent back-end processes, which can lower the possibility of cracks appearing in the conductive member 30 formed in the through hole VH. After the second electroplating process is performed, step (6-1), i.e., an annealing process, can be selectively performed to reduce internal stress in the conductive member 30 and/or change the microstructure of the conductive member 30.

In some embodiments, the material of the bridge 20B and the conductive member 30 may comprise copper (Cu), titanium (Ti), titanium nitride (TiN), tantalum (Ta), tungsten (W), platinum (Pt), nickel (Ni), gold (Au), silver (Ag), or a combination thereof.

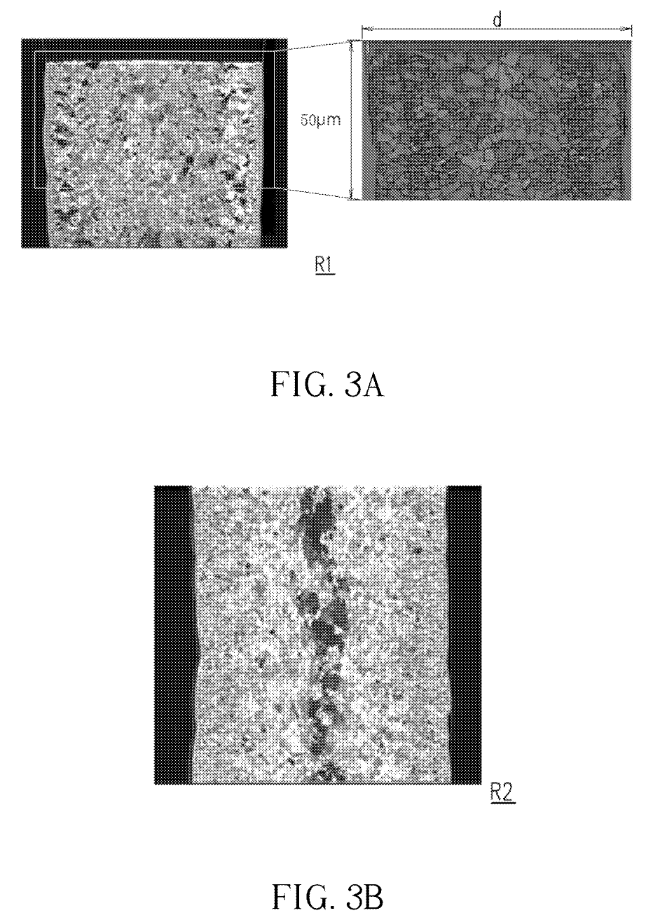

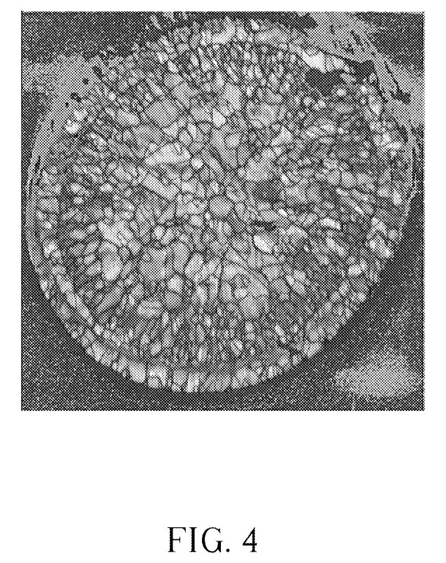

After the second electroplating process, a surface planarization step can be performed so that a surface of the conductive member 30 is almost coplanar with a surface of the substrate 10. That is, in the direction Z, a distance between the surface of the conductive member 30 and the surface of the substrate 10 is less than or equal to 10 micrometers. Please refer to FIG. 3A. After the planarization step, in a cross-sectional region extending 50 μm from a surface 30s1 of the conductive member 30 in the direction Z, an average grain size of the conductive member 30 is less than or equal to 5 μm, and a maximum particle size of the conductive member 30 is less than 20 μm, wherein the conductive member 30 is calculated by using a suitable instrument in the cross-sectional region circled in FIG. 3A (its surface area is the product of the diameter W and 50 μm). Please refer to FIG. 4. In a top-view surface area of the surface 30s1 of the conductive member 30 in the direction Z and in a top-view surface area of a surface 30s2 of the conductive member 30 in the direction Z (not shown), an average grain size of the conductive member 30 is less than or equal to 6 μm. Please refer to FIG. 3B, which shows a cross-sectional region of the conductive member 30 near the center. According to some embodiments, the maximum particle size in the cross-sectional region and in the top-view surface area is not greater than 20μm, or not greater than 15μm.

At this point, the fabrication of the substrate structure 100 is completed.

Step (7) is performed: performing a second inspection process.

In this embodiment, the second inspection process comprises: (c) checking whether an average grain size of the conductive member 30 is less than or equal to 5μm in a cross-sectional region extending 50μm from the surface 30s1 of the conductive member 30 in the direction Z; and (d) checking whether an average grain size of the conductive member 30 is less than or equal to 6 micrometers in a top-view surface area of the surface 30s1 and the surface 30s2 of the conductive member 30 in the direction Z. If at least one of the parameters defined in step (c) and step (d) is not met or out of spec, returning to step (6-1) or discarding this substrate structure may be considered.

In some embodiments, whether the plurality of through holes VH meet the parameters defined in step (c) and step (d) can be confirmed by an optical inspection system or a scanning electron microscope, but the present disclosure is not limited to.

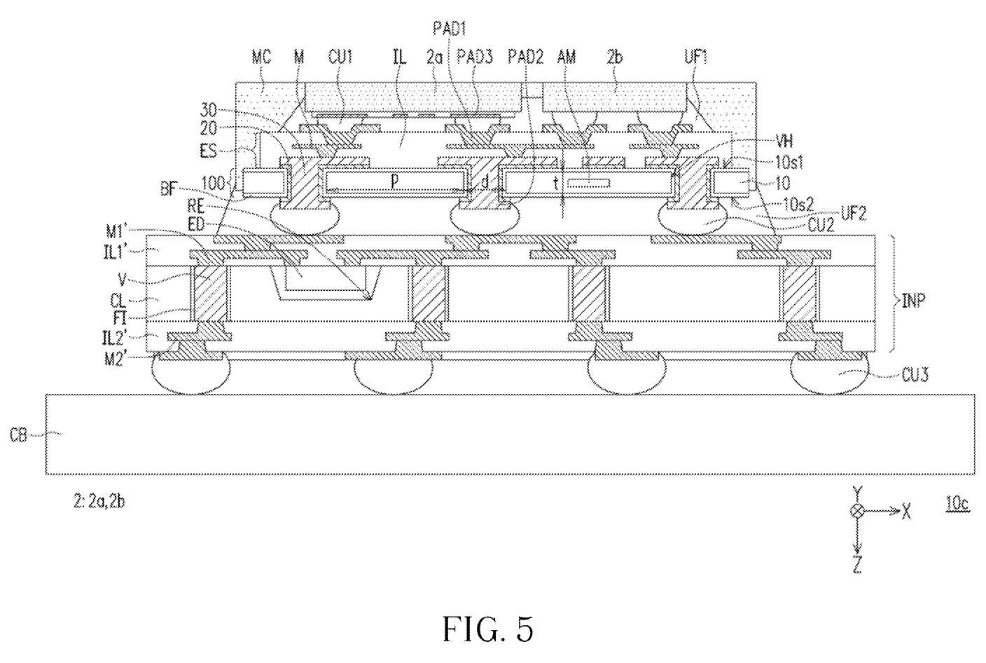

After the second inspection process is performed, the substrate structure 100 can be applied in back-end processes to form a corresponding electronic device. According to some embodiments, a singulation step may be further included to separate the substrate structure 100 into a plurality of sub-substrates by dicing or laser grooving, but the present disclosure is not limited to. For example, step (8) can be performed: performing at least one process on the substrate structure 100 to form the electronic device 10c as shown in FIG. 5.

In this embodiment, a corresponding at least one process can be performed on the substrate structure 100 to form the electronic device 10c, which may comprise performing processes of forming a circuit structure ES and forming an electronic component 2 on the substrate structure 100, but the present disclosure is not limited to.

Please refer to FIG. 5. In this embodiment, the circuit structure ES is disposed on the surface 10s1 of the substrate 10 and at least partially is overlapped with the plurality of through holes VH. In some embodiments, the circuit structure ES comprises at least one insulating layer IL and at least one conductive layer M. The material of the insulating layer IL may comprise Ajinomoto Build-up Film (ABF), photosensitive polyimide (PSPI), polyimide (PI), epoxy resin, or other suitable insulating materials. The conductive layer M may comprise a suitable conductive material similar to the conductive member 30.

A thickness t of the substrate 10 is from 0.6 mm to 2 mm, and a coefficient of thermal expansion of the substrate 10 is from 1 ppm/K to 10 ppm/K. Along the X direction, a minimum aperture d of one of the plurality of through holes VH is from 90 μm to 110 μm, and an aspect ratio (AR) of the plurality of through holes VH is from 8 to 20, wherein the aspect ratio = thickness t of the substrate / a minimum aperture d of one of the plurality of through holes VH (AR=t/d). Along X direction, a pitch P between two adjacent through holes of the plurality of through holes VH is less than or equal to 200 μm. The term "adjacent" or "adjoining" in the present disclosure refers to two of a plurality of elements (e.g., the plurality of through holes VH) being arranged along a direction, and these two having a minimum distance or minimum pitch.

Please refer to FIG. 2. Before the annealing process, in a cross-sectional region extending 50 micrometers from the surface 30s1 of the conductive member 30 in the direction Z (or from the surface 30s2 in a direction opposite to the direction Z), an average grain size of the conductive member 30 is less than or equal to 5 μm. Wherein, an average grain size of the bridge 20B and the first portion 30a is less than or equal to 5 μm, an average grain of the second portion 30b may be greater than or equal to an average grain of the first portion 30a, and an average grain of the third portion 30c may be greater than or equal to the average grain of the first portion 30a. In some embodiments, after the annealing process or after forming the circuit structure ES, an average grain size of the third portion 30c of the conductive member 30 is greater than or equal to 2 μm and less than or equal to one-fifth of the minimum aperture d of the one of the plurality of through holes VH, which can reduce the risk of the substrate 10 cracking. The bridge 20B referred to in the present disclosure is the conductive member 30 adjacent to the sidewall of the through hole VH and having a continuous structure at the center of the through hole VH (where the width of the through hole VH is smallest). The first portion 30ais within a range of 10 micrometers from a sidewall of the bridge 20B along the X direction, the second portion 30b is within a range of 15 micrometers from a sidewall of the first portion 30a along the X direction, and the rest is the third portion 30c.

In this embodiment, the multilayer conductive layer M of the circuit structure ES comprises a contact pad PAD1 and a contact pad PAD2. The contact pad PAD1 is, for example, located on one side of the surface 10s1 of the substrate 10, is a part of the multilayer conductive layer M farthest from the surface 10s1 of the substrate 10, and is exposed by the multilayer insulating layer IL. The contact pad PAD2 is, for example, located on one side of the surface 10s2 of the substrate 10. In this embodiment, at least a portion of the multilayer conductive layer M is disposed in the plurality of through holes VH to establish an electrical connection path between the contact pad PAD1 and the contact pad PAD2.

In this embodiment, the circuit structure ES comprises a redistribution structure, which can be used for rerouting lines and/or further increasing the fan-out area of the lines. The purpose of providing the redistribution structure is to extend connections to a wider pitch or to re-route connections to another connection with a different pitch. Based on this, electronic components 2 that are the same as or different from each other can be disposed on the circuit structure ES and electrically connected to it. An external component CB can be disposed on the surface 10s2 of the substrate 10 and electrically connected to the circuit structure ES through the through holes VH, such that the electronic component 2 can be electrically connected to the external component CB through the circuit structure ES. The external component CB may comprise a circuit board, an IC substrate, or other suitable components. The method for forming the circuit structure ES comprises electroplating, electroless plating, etching, laser, photolithography, and annealing steps, or other suitable methods.

In this embodiment, the electronic device 10c further comprises a buffer layer BF. The material of the buffer layer BF may comprise suitable organic materials and/or inorganic materials. The material of the buffer layer BF may comprise polyimide, parylene, benzocyclobutene (BCB) resin, epoxy resin, benzocyclobutene (BCB), polycarbonate (PC), polyethylene terephthalate (PET), polyethylene naphthalate (PEN), silicon-containing compounds, or combinations thereof, but the present disclosure is not limited thereto. In some embodiments, the buffer layer BF may comprise a multilayer stack structure of inorganic layer/organic layer/inorganic layer. In some embodiments, the buffer layer BF may cover the side of the substrate 10 and the sidewall of the through hole VH, and can fill pits, unevenness, or micro-cracks generated on the corresponding surface of the substrate 10 during the manufacturing process, reducing the cracking of the substrate 10.

A plurality of electronic components 2 are, for example, disposed on the circuit structure ES and are electrically connected to the circuit structure ES. In this embodiment, the plurality of electronic components 2 comprise two electronic components 2a, 2b, but the present disclosure is not limited to this quantity. The electronic components 2a, 2b can be, for example, a high-bandwidth memory, a dynamic random-access memory (DRAM), a static random-access memory (SRAM), a cache memory, a graphic processing unit (GPU), a central processing unit (CPU), a digital signal processor (DSP), or an application-specific integrated circuit (ASIC), but the present disclosure is not limited thereto. The electronic component 2a can be electrically connected to the circuit structure ES through a contact pad PAD3 and at least a portion of a plurality of connection units CU1, and the electronic component 2b can be electrically connected to the circuit structure ES through at least another portion of the plurality of connection units CU1.

In this embodiment, the electronic device 10c further comprises a plurality of connection units CU1 disposed on the circuit structure ES, so that the circuit structure ES can be electrically connected to the electronic component 20 through the plurality of connection units CU1. The material of the plurality of connection units CU1 may comprise tin, copper, nickel, silver, gold, gallium, or other suitable materials.

In this embodiment, the electronic device 10c further comprises an encapsulation layer MC surrounding the substrate 10 and surrounding the plurality of electronic components 2. In this embodiment, the encapsulation layer MC may expose parts of the plurality of electronic components 2. Specifically, an upper surface of the encapsulation layer MC may be aligned with a non-active surface of the plurality of electronic components 2, but the present disclosure is not limited thereto.

In this embodiment, the electronic device 10c further comprises an underfill layer UF1 disposed between the substrate 10 and the electronic component 2, and filling the space between adjacent connection elements CU1. In some embodiments, the underfill layer UF1 may be surrounded by the encapsulation layer MC.

In this embodiment, the electronic device 10c further comprises a plurality of connection units CU2 disposed on one side of the surface 10s2 of the substrate 10 and electrically connected to the contact pad PAD2 in the circuit structure ES, so that the circuit structure ES can be electrically connected to an external component CB through the plurality of connection units CU2. In some embodiments, it can be electrically connected to the external component CB through alignment marks AM in the substrate 10. The material of the plurality of connection units CU2 can be the same as or similar to the material of the plurality of connection units CU1.

In this embodiment, the electronic device 10c further comprises an underfill layer UF2 disposed between the substrate 10 and the external component CB, and filling the space between adjacent connection elements CU2. In some embodiments, the underfill layer UF2 may be in contact with a sidewall of the encapsulation layer MC. The material of the encapsulation layer MC, the underfill layer UF1, and the underfill layer UF2 may comprise suitable inorganic materials or organic materials.

In this embodiment, the electronic device 10c further comprises an interposer INP, for example, comprising a core layer CL, vias V, an insulating layer IL1', a conductive layer M1', an insulating layer IL2', and a conductive layer M2'. The material of the core layer CL can be, for example, silicon, glass, or an organic material. In some embodiments, an edge of the core layer CL may have a chamfer or a rounded corner, but the present disclosure is not limited thereto. A plurality of vias V are, for example, disposed and penetrate the core layer CL. In some embodiments, the via V may also comprise a filling material FI disposed on a sidewall of the via V. The insulating layer IL1' and the conductive layer M1' are, for example, disposed above the core layer CL and are located between the core layer CL and the substrate structure 100 in the direction Z. The insulating layer IL1' and the conductive layer M1' can be combined to form a redistribution structure, so that the conductive member 30 in the substrate structure 100 can be electrically connected to the via V in the core layer CL. The insulating layer IL2' and the conductive layer M2' are located between the core layer CL and the external component CB in the direction Z. The insulating layer IL2' and the conductive layer M2' can be combined to form a redistribution structure, so that the external component CB can be electrically connected to the via V in the core layer CL through a connection unit CU3. According to some embodiments, the plurality of electronic components 2 can be electrically connected to the circuit board CB through the interposer INP. Wherein, the formation method of the via V may same with the formation method of the conductive member 30. So as to say, after the annealing process, an average grain size of the third portion of the via V is greater than or equal to 2 μm and less than or equal to one-fifth of the minimum aperture of the plurality of through holes of the interposer INP, which can reduce the risk of cracking.

According to some embodiments, the interposer INP may comprise an embedded die ED disposed in a recess RE of the core layer CL, which can be electrically connected to the via V in the core layer CL through the conductive layer M1'.

In this embodiment, the electronic device 10c further comprises a plurality of connection units CU3 disposed below the interposer INP and electrically connected to the conductive layer M2' in the interposer INP, so that the interposer INP is electrically connected to the external component CB through the plurality of connection units CU3.

In summary, in the manufacturing method of an electronic device provided by some embodiments of the present disclosure, by adjusting the current density and/or the electroplating time in the electroplating process, the grain size of the material of the conductive member formed in the through hole can be defined. This can reduce the possibility of the substrate structure cracking after undergoing thermal processes, thereby improving the yield of manufacturing the electronic device.

What is claimed is:

1. A substrate structure of an electronic device, comprising:
a substrate;
a plurality of through holes penetrating the substrate, wherein a pitch between two adjacent through holes of the plurality of through holes is less than or equal to 200 μm; and
a conductive member disposed in at least one of the plurality of through holes,
wherein, in a cross-sectional view of the substrate structure, the conductive member has a bridge, a first portion, a second portion, and a third portion sequentially disposed along a normal direction of the substrate, the bridge is adjacent to a sidewall of the at least one of the plurality of through holes, the first portion is adjacent to a sidewall of the bridge, and the first portion has an average grain size less than or equal to 5 μm.

2. The substrate structure of the electronic device according to claim 1, wherein the second portion has an average grain size less than or equal to 5 μm.

3. The substrate structure of the electronic device according to claim 1, wherein the substrate is a glass substrate.

4. The substrate structure of the electronic device according to claim 1, wherein a thickness of the substrate is from 0.6 mm to 1 mm, and a minimum aperture of one of the plurality of through holes is from 90 μm to 110 μm.

5. The substrate structure of the electronic device according to claim 4, wherein an average grain size of the third portion is greater than 2 μm and less than or equal to one-fifth of the minimum aperture of the one of the plurality of through holes.

6. The substrate structure of the electronic device according to claim 1, wherein the substrate has a coefficient of thermal expansion from 1 ppm/K to 10 ppm/K.

7. The substrate structure of the electronic device according to claim 1, wherein the plurality of through holes have an aspect ratio from 8 to 20.

8. A manufacturing method of an electronic device, comprising:
providing a substrate structure, wherein providing the substrate structure comprises:
providing a substrate having a plurality of through holes;
performing an electroplating process to form a conductive member in at least one of the plurality of through holes, comprising:
performing a first electroplating process to form a bridge of the conductive member in the at least one of the plurality of through holes; and
performing a second electroplating process to form other portions of the conductive member connected to the bridge in the at least one of the plurality of through holes,
wherein, in a cross-sectional view of the substrate structure, the other portions of the conductive member have a first portion, a second portion, and a third portion sequentially disposed along a normal direction of the substrate, the first portion is adjacent to a sidewall of the bridge, and the first portion has an average grain size less than or equal to 5 μm, wherein a pitch between two adjacent through holes of the plurality of through holes is less than or equal to 200 μm; and
performing at least one process on the substrate structure to form the electronic device,
wherein a current density and an electroplating time used in the first electroplating process are greater than a current density and an electroplating time used in the second electroplating process.

9. The manufacturing method of the electronic device according to claim 8, wherein the first electroplating process comprises a pulse periodic reverse electroplating process, and the second electroplating process comprises a multi-stage direct current electroplating process.

10. The manufacturing method of the electronic device according to claim 9, wherein the second electroplating process comprises three stages of direct current electroplating processes, a current density sequentially increases through the three stages of the direct current electroplating processes, and an electroplating time sequentially decreases through the three stages of the direct current electroplating processes.

11. The manufacturing method of the electronic device according to claim 8, further comprising:
before forming the bridge in the at least one of the plurality of through holes, forming a seed layer in the plurality of through holes.

12. The manufacturing method of the electronic device according to claim 11, further comprising:
performing a pretreatment process on the seed layer.

13. The manufacturing method of the electronic device according to claim 8, further comprising:
after forming the bridge in the at least one of the plurality of through holes, performing a first inspection process.

14. The manufacturing method of the electronic device according to claim 13, wherein the first inspection process comprises:
checking whether the bridge is formed; and
checking a formation position of the bridge.

15. The manufacturing method of the electronic device according to claim 14, wherein after performing the first inspection process, if the bridge is not formed, another pretreatment process is performed on the seed layer.

16. The manufacturing method of the electronic device according to claim 14, wherein after performing the first inspection process, if the bridge is not formed in a region extending from a first surface of the substrate along the normal direction by 0.25 times to 0.75 times a thickness of the substrate, another pretreatment process is performed on the seed layer.

17. The manufacturing method of the electronic device according to claim 8, further comprising:
after forming the conductive member in the at least one of the plurality of through holes, performing a annealing process.

18. The manufacturing method of the electronic device according to claim 17, further comprising:
after performing the annealing process, performing a second inspection process.

19. The manufacturing method of the electronic device according to claim 18, wherein the second inspection process comprises:
checking whether an average grain size of the conductive member is less than or equal to 5 μm in a cross-sectional region extending 50 μm from a first surface of the conductive member along a normal direction; and
checking whether the average grain size of the conductive member is less than or equal to 6 μm in a top-view surface area of the first surface and a second surface of the conductive member in the normal direction.

20. The manufacturing method of the electronic device according to claim 19, wherein after performing the second inspection process, if at least one of the average grain size requirements of the conductive member is out of spec, another annealing process is performed.
